(19) United States
(12) Patent Application Publication
(10) Pub. No.: US 2006/0179399 A1
(43) Pub. Date: Aug. 10, 2006

(54) Method and recorder for recording data on a record carrier

(76) Inventors: Robert Albertus Brondijk, Eindhoven (NL); Stephanus Josephus Maria Van Beckhoven, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/562,881

(22) PCT Filed: Jun. 25, 2004
(86) PCT No.: PCT/IB04/51005

§ 371 Date: Dec. 29, 2005

(30) Foreign Application Priority Data
Jun. 30, 2003 (EP) 03077078.8

(51) Int. Cl. H03M 13/00

(52) U.S. Cl. 714/776

(57) ABSTRACT

When a write error occurs on a write once recording medium the recording medium is currently discarded. By retrieving the location of the last recorded data block from the recorded area indicator on the recording medium a starting point for the search for the next empty data block suitable for recording is obtained. By searching for an empty data block the data blocks comprising write errors following the last recorded data block are skipped and the recording is continued at the empty data block found. After finishing the recording and writing the lead-in and lead-out information a record carrier is obtained that can be played in standard players.

The invention relates to a method for recording data on a write once record carrier with sequential write access and a recorded area indicator and a last recorded data block with a location,

comprising the steps of

recording information in a data block

updating the recorded area indicator to reflect the recording of information in the data block

and to a recorder for recording information on a write once record carrier with sequential write access and a recorded area indicator and a last recorded data block with a location, the recorder comprising a controller means, writing means, data retrieval means, and location of last recorded data block where the control means is operative to record information in a data block sequentially following the last recorded data block.

Such a method is known from state of the art recorders for optical recording media. An example of such a recorder is a DVD or Blue Disk recorder capable of recording on a DVD+R or DVD-R or Blue Disk recording medium They comply with the DVD+R or Blue Disk standard. Those standards prescribes that when a recording is resumed on a write once medium the data block following the last recorded data block must be the first data block to be recorded. On the recording medium defects can be present in ECC blocks that lead to errors in the data recorded in those ECC blocks. The recorder aborts the recording when an error is detected in an ECC block.

When recording video data in DVD+VR format all of the video data is placed in a single track. A write error resulting in a defect ECC block results in an unusable recording medium.

The draw back of such a method is that the recorder must discard the write once record carrier.

It is an objective of the present invention to provide a method for recording on a recording medium that allows the recording to be resumed regardless of the presence of data blocks comprising a write error.

To achieve this objective the method is characterized in that the method further comprises the following steps if a data block with write error is detected:

determining the location of the last recorded data block using information from the recorded area indicator;

searching for an empty data block sequentially following the last recorded data block

recording information in the empty data block sequentially following the last recorded data block.

Instead of discarding the recording medium the recording can be resumed by searching a section of the record carrier comprising a limited number of data blocks as indicated by the recorded area indicator as comprising the last recorded data block, skipping the data block or data blocks that sequentially follow last recorded data block by searching for an empty data block and resuming the recording starting with the empty data block found. A playback device that will later playback the record carrier is not affected by the skipped data blocks since it will ignore these data blocks and will continue the playback with the first sequentially found data block that is not defective.

The record carrier no longer has to be discarded during the recording operation because of a write error, thus achieving the objective of the invention.

The recorded area indicator provides an indication which section of the recording medium is already recorded and which section remains empty. Because the recording medium is recorded in a sequential fashion, the last recorded data block can be found at the boundary between the section already recorded and the section that is still empty.

The presence of skipped data blocks in the section already recorded is consequently of no influence to the searching of the last recorded data block when using this method, rendering a recording medium with skipped data blocks suitable for resuming recordings.

An embodiment of the method is characterized in that the information from the recorded area indicator comprises an indication of a set of contiguous data blocks comprising the last recorded data block.

The recorded area indicator represents the data blocks already recorded with an entry in the recorded area indicator. Each entry represents a predetermined number of data blocks. Consequently an entry can represent a single data block or it can represent multiple data blocks. When the entry represents a single data block, applying the method only involves determining the last entry in the recorded area indicator, and translating this entry into the exact location of the last recorded data block. When the entry represents multiple recorded data blocks, applying the method involves determining the set of data blocks comprising the last recorded data block and subsequently searching this limited number of data blocks on the recording medium to find the last recorded data block. Subsequently after the last recorded data block has been found the data blocks comprising a write error are skipped by searching for an empty data block. A data block comprising a write error is not empty so searching for an empty data block automatically means that data blocks comprising a write error are skipped because they do not qualify as empty.

A further embodiment of the method is characterized in that based on the indication of a set of contiguous data blocks comprising the last recorded data block the set of contiguous data blocks is searched for the location of the last recorded data block.

When the entry represents multiple recorded data blocks, applying the method involves determining the set of data blocks comprising the last recorded data block and subsequently searching this limited number of data blocks on the recording medium to find the last recorded data block.

Because this search is limited to the set of data blocks indicated by the recorded area indicator as comprising the last recorded data block the search can be performed in an acceptable amount of time.

Even if the set of data blocks indicated by the recorded area indicator as comprising the last recorded data block comprises skipped data blocks, the search is not hampered because the last recorded data block can be found by searching from the end of the set of data blocks, thus completely ignoring the presence of skipped data blocks before the last recorded data block because the search does not involve the data blocks before the last recorded data block.

Alternatively the search can start from the beginning of the set of data blocks indicated by the recorded area indicator. When skipped data blocks are encountered the search can continue in order to ensure that the last recorded data block is found.

Since the search does not extend beyond the set of data blocks indicated by the recorded area indicator the search effort is still limited and can be performed in an acceptable amount of time.

In this way the recorder does no longer need to search the entire disk and is no longer affected by the presence of skipped data blocks, making it feasible to resume recording on the recording medium in an acceptable amount of time.

Well known techniques for finding the first empty data block sequentially following the last recorded data block can be applied.

A recorder according to the invention is characterized in that the controller means is coupled to the data retrieval means and is operative to retrieve the recorded area indicator using the data retrieval means and is further operative to search an empty data block sequentially following the last recorded data block using the data retrieval means and the recorded area indicator.

Instead of searching the entire recording medium to locate the last recorded data block the recorder can retrieve the recorded area indicator from the recording medium. The recorded area indicator provides an indication which section of the recording medium is already recorded and which section remains empty. Because the recording medium is recorded in a sequential fashion, the last recorded data block can be found at the boundary between the section already recorded and the section that is still empty.

The presence of skipped data blocks in the section already recorded is consequently of no influence to the searching of the last recorded data block when using this method, rendering a recording medium with skipped data blocks suitable for resuming recordings.

By subsequently searching for an empty data block sequentially following the last recorded data block any data block comprising a write error are skipped and the recording can be resumed starting at the empty data block.

Thus the loss of the write once recording medium is avoided.

An embodiment of the recorder is characterized in that the recorded area indicator comprises an indication of a set of contiguous data blocks comprising the last recorded data block.

The recorded area indicator represents the data blocks already recorded with an entry in the recorded area indicator. Each entry represents a predetermined number of data blocks. Consequently an entry can represent a single data block or it can represent multiple data blocks. When the entry represents a single data block, applying the method only involves determining the last entry in the recorded area indicator, and translating this entry into the exact location of the last recorded data block. When the entry represents multiple recorded data blocks, applying the method involves determining the set of data blocks comprising the last recorded data block and subsequently searching this limited number of data blocks on the recording medium to find the last recorded data block.

A further embodiment of the recorder is characterized in that based on the indication of a set of contiguous data blocks comprising the last recorded data block the set of contiguous data blocks is searched for the location of the last recorded data block.

When the entry represents multiple recorded data blocks, applying the method involves determining the set of data blocks comprising the last recorded data block and subsequently searching this limited number of data blocks on the recording medium to find the last recorded data block.

Because this search is limited to the set of data blocks indicated by the recorded area indicator as comprising the last recorded data block the search can be performed in an acceptable amount of time.

Even if the set of data blocks indicated by the recorded area indicator as comprising the last recorded data block comprises skipped data blocks, the search is not hampered because the last recorded data block can be found by searching from the end of the set of data blocks, thus completely ignoring the presence of skipped data blocks before the last recorded data block because the search does not involve the data blocks before the last recorded data block.

Alternatively the search can start from the beginning of the set of data blocks indicated by the recorded area indicator. When skipped data blocks are encountered the search can continue in order to ensure that the last recorded data block is found.

Since the search does not extend beyond the set of data blocks indicated by the recorded area indicator the search effort is still limited and can be performed in an acceptable amount of time.

In this way the recorder does no longer need to search the entire disk and is no longer affected by the presence of skipped data blocks, making it feasible to resume recording on the recording medium in an acceptable amount of time.

The invention will now be discussed based on figures.

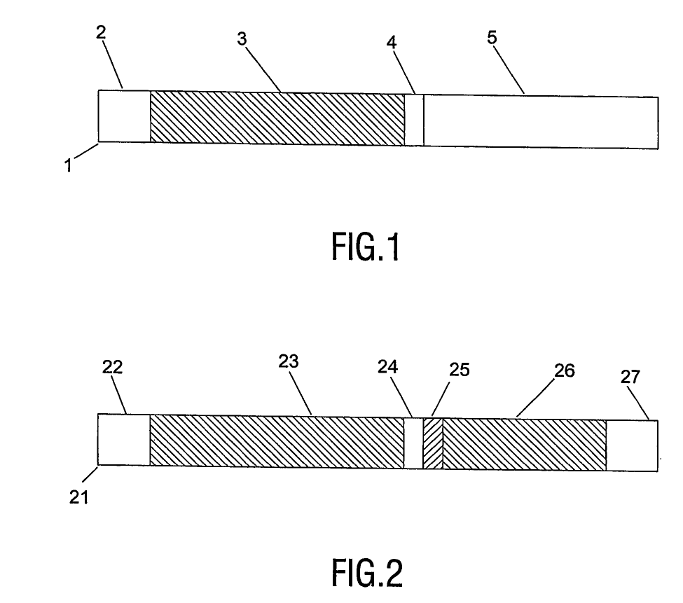

FIG. 1 shows a disc with a write error as resulting from applying the prior art.

FIG. 2 shows a disc with a write error as recorded using the present invention.

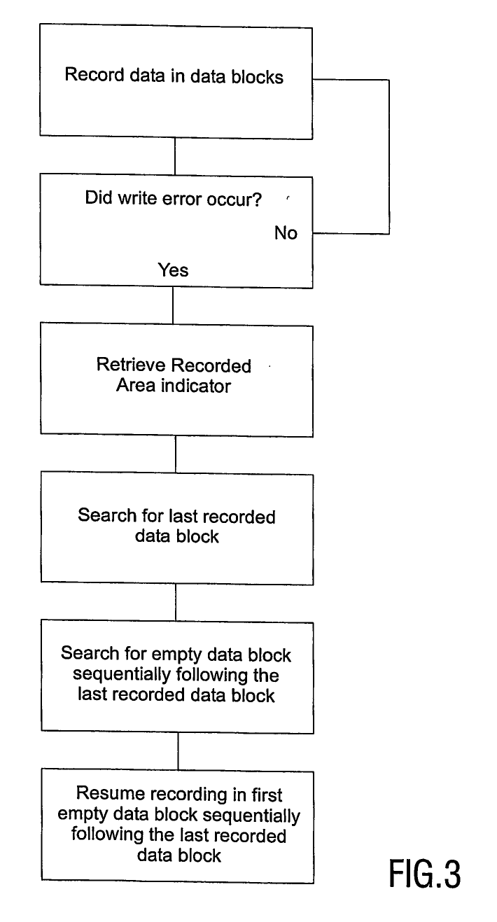

FIG. 3 shows a flow diagram of the method of the invention.

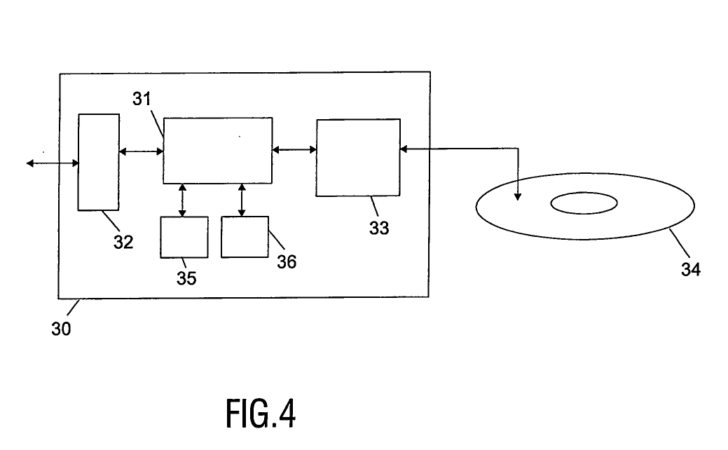

FIG. 4 shows a recorder.

FIG. 1 shows a disc with a write error as resulting from applying the prior art.

A track 1 on a record carrier comprises a lead-in section 2 reserved for writing lead-in information, a recorded area 3, a data block comprising data block 4 comprising a write error and an empty section 5 comprising empty data blocks.

When the recorder starts recording the data on the record carrier it successively writes sequentially arranged data blocks. This results in a recorded area 3. The lead-in information and lead-out information is at this point not yet recorded since that is done when the entire track 1 has been recorded.

When the recorder encounters a data block 4 comprising a write error, which may be caused by surface damage or contamination or a loss of tracking during the write operation, the recorder aborts the recording operation. Consequently the empty section comprising empty data blocks will not be recorded. The lead-in and lead-out information are not recorded on the record carrier resulting in an un-useable record carrier.

FIG. 2 shows a disc with a write error as recorded using the present invention

A track 21 on a record carrier comprises a lead-in section 22 reserved for writing lead-in information, a recorded area 23, a data block comprising data block 24 comprising a write error and an empty section 25,26,27 comprising empty data blocks.

When the recorder starts recording the data on the record carrier it successively writes sequentially arranged data blocks. This results in a recorded area 23. The lead-in information and lead-out information is at this point not yet recorded since that is done when the entire track 21 has been recorded.

When the recorder encounters a data block 24 comprising a write error, which may be caused by surface damage or contamination or a loss of tracking during the write operation, the recorder aborts the recording operation. Subsequently the recorder retrieves the recorded area indicator from the record carrier. Based on the recorded area indicator the recorder searches for the last recorded data block which is the last correctly recorded data block of the recorded are 23. Once this last recorded data block is found the recorder searches for an empty data block 25 sequentially following on the last recorded data block, i.e. subsequently following on the recorded area 23. The data block 24 comprising the write error is not empty since some data has been written and is thus skipped by the recorder. The recorder resumes the recording with the first empty data block 25 found, completing the recording by recording the remaining data section 26 of the track.

Finally the lead-in information is recorded in the lead-in section 22 and the lead-out information is recorded in the lead-out section 27.

The result of this is a record carrier that can be played by playback devices since all relevant information is present on the record carrier and the data block 24 skipped during recording is also skipped by the playback device because of the read error resulting from the write error. The record carrier is thus no longer discarded by the recorder.

FIG. 3 shows a flow diagram of the method of the invention

The first step comprises the recording of data in data blocks.

Subsequently, in the second step the recorder checks whether write errors occurred.

This can be done via data verification, i.e. read after write, or by detecting loss of tracking. If no write error is detected the recorder returns to the first step and the recording operation is continued if required

When a write error is detected the recorder aborts the recording operation and proceeds to the third step where the recorded area indicator is retrieved, either from memory or from the record carrier. Retrieving the recorded area indicator from the record carrier allows the record carrier to be removed from the recorder before resuming the recording operation, for instance to clean the surface of the record carrier. The recorded area indicator provides information about which groups of data blocks have been recorded and which data blocks are still available for recording. Because the record carrier is sequentially recorded the last entry in the recorded area indicator indicating a recorded group of data blocks corresponds to a group of data blocks on the record carrier comprising the last recorded data block.

In the fourth step the recorder searches the group of data blocks indicated by the recorded area indicator as comprising the last recorded data block for the last recorded data block.

Following this last recorded data block there may be data block comprising write errors and the recorder must ensure that no new attempt to record data in these data blocks is attempted. The recorder instead searches, in the fifth step, for the next available empty data block sequentially following on the last recorded data block and thus also following the data blocks comprising a write error. In the sixth step the recorder resumes the recording in the first empty data block sequentially following the last recorded data block as found in respectively the fourth step and the fifth step.

It is clear that the recorder with the sixth step effectively returns to the state of the first step when writing, i.e. further write errors lead to a repeat of the procedure outlined in FIG. 3.

Once all data has been recorded the record carrier is finalized by recording the lead-in and lead-out information.

FIG. 4 shows a recorder

The recorder 30 for recording information on a record carrier comprises a processor 31 coupled to an interface 32 for receiving a format command or a close track session command through the interface 32 and is coupled to writing/reading means 33 in the form of a basic bit engine for writing data.

The processor 31 receives information from the writing/reading means 33 about write errors, for instance information about loss of tracking during the recording operation.

The processor processes this information about write errors and provides this information to a higher level application or another device coupled to the recorder via the interface 32. Alternatively the recorder 30 may act on the write error information independently and provide no information about the write error via the interface 32.

The recorder further comprises a memory 35 coupled to the processor 31, and a user I/O device such as a keyboard/screen combination 36.

The method may be used by either the recorder 30 or the higher level application or the method may be split up in tasks where the tasks are divided over the recorder and the higher level application such as a video recording application.

For instance the recording of the data can be controlled by the higher level application while the detection of the write errors must be performed by the recorder. The determination of the last recorded data block based on the recorded area indicator information can be performed by the higher level application while the search for an empty data block can be delegated to the recorder 30.

If the recorder 30 is powered down after the detection of a write error but before the resumption of the recording operation or the record carrier is ejected, the retrieval of the recorded area indication from the record carrier allows the recording operation to be resumed. If the recorded area indicator were not used the time needed to locate the last recorded data block would become excessive.

If the recorder 30 receives the eject disc command via the interface 32 the recorder 30 operates the loading means (not shown) to eject the record carrier comprising the updated recorded area indicator.

1. Method for recording data on a write once record carrier with sequential write access and a recorded area indicator and a last recorded data block with a location, comprising the steps of
recording information in a data block
updating the recorded area indicator to reflect the recording of information in the data block
characterized in that the method further comprises the following steps if a data block with write error is detected:
determining the location of the last recorded data block using information from the recorded area indicator;
searching for an empty data block sequentially following the last recorded data block
recording information in the empty data block sequentially following the last recorded data block.

2. Method as claimed in claim 1, characterized in that the information from the recorded area indicator comprises an indication of a set of contiguous data blocks comprising the last recorded data block.

3. Method as claimed in claim 2, characterized in that based on the indication of a set of contiguous data blocks comprising the last recorded data block the set of contiguous data blocks is searched for the location of the last recorded data block.

4. Recorder for recording information on a write once record carrier with sequential write access and a recorded area indicator and a last recorded data block with a location, the recorder comprising a controller means, writing means, data retrieval means, and location of last recorded data block where the control means is operative to record information in a data block sequentially following the last recorded data block, characterized in that the controller means is coupled to the data retrieval means and is operative to retrieve the recorded area indicator using the data retrieval means and is further operative to search an empty data block sequentially following the last recorded data block using the data retrieval means and the recorded area indicator.

5. Recorder as claimed in claim 4, characterized in that the recorded area indicator comprises an indication of a set of contiguous data blocks comprising the last recorded data block.

6. Recorder as claimed in claim 5, characterized in that based on the indication of a set of contiguous data blocks comprising the last recorded data block the set of contiguous data blocks is searched for the location of the last recorded data block.
